(19) United States
(12) Patent Application Publication
(10) Pub. No.: US 2024/0016029 A1
(43) Pub. Date: Jan. 11, 2024

(54) DISPLAY PANEL

(71) Applicant: Qing Tu, Wuhan (CN)

(72) Inventor: Qing Tu, Wuhan (CN)

(21) Appl. No.: 17/419,711

(22) PCT Filed: Jun. 7, 2021
(86) PCT No.: PCT/CN2021/098669

§ 371 Date: Dec. 1, 2022

(51) Int. Cl. H10K 59/80; H10K 59/123

(52) U.S. Cl. CPC H10K 59/80518; H10K 59/80521; H10K 59/80515; H10K 59/123; H10K 2102/103

(57) ABSTRACT

A display panel is provided. The display panel includes an array substrate and an anode layer disposed on the array substrate. The anode layer includes a first conductive layer and a second conductive layer located on the first conductive layer. A surface of the first conductive layer toward the second conductive layer is provided with a first grating structure. A light emitting layer is disposed on the second conductive layer. By disposing the first grating structure on the first conductive layer, surface plasmon effect and waveguide effect occurring in a dielectric layer near the anode are weakened.

### BACKGROUND OF INVENTION

### Field of Invention

The present application relates to the field of display technology and particularly to a display panel.

### Description of Prior Art

In recent years, commercialization standards of organic light emitting diode (OLED) display technology used on flat-panel displays have been continuously improved. Benefiting from continuous deepening and improvement of OLED commercialization researches, OLED screens have been provided with characteristics of high brightness, high contrast, wide color gamut, etc. However, there are still some problems that need to be solved and improved urgently in processes and technology.

OLED devices are devices that convert electrical energy into light energy, and their light output efficiency is a ratio of an actual photon energy emitted by devices to a total photon energy produced by the devices, reflecting a utilization rate of light energy used by the OLED devices. Part of the photon energy emitted by light emitting units of the OLED devices can be consumed by a surface plasmon effect on metal interfaces and a waveguide effect in organic layers, resulting in reduction of light extraction efficiency. The surface plasmon effect mainly occurs at interfaces between metal anodes and adjacent dielectric layers of the OLED devices, and interfaces between metal cathodes and the adjacent dielectric layers. This effect consumes about 40% of the total produced light. The waveguide effect mainly occurs in organic light emitting functional layers of the OLED devices, which consumes about 40% of the total produced light. Under same display conditions, low light extraction efficiency will lead to increased power consumption and shortened service life of the OLED devices.

A technical problem of low light extraction efficiency caused by surface plasmon effect and waveguide effect exists in current display devices.

### SUMMARY OF INVENTION

The present application provides a display panel configured to remedy the technical problem of low light extraction efficiency caused by surface plasmon effect and waveguide effect in current display devices.

The present application provides a display panel, including:
an array substrate;
an anode layer disposed on the array substrate and including a first conductive layer and a second conductive layer located on the first conductive layer, wherein a surface of the first conductive layer toward the second conductive layer is provided with a first grating structure; and
a light emitting layer disposed on the second conductive layer.

In the display panel of the present application, the first conductive layer is a light-reflecting conductive layer, and the second conductive layer is a light-transmitting conductive layer.

In the display panel of the present application, the first grating structure includes a plurality of first grooves and a plurality of first convex portions close to the first grooves.

In the display panel of the present application, a cross-sectional shape of the first convex portions along a direction perpendicular to a plane where the first conductive layer is located is any one of square, triangular, trapezoidal, or arc.

In the display panel of the present application, the first grooves extend from a first end of the first conductive layer to a second end of the first conductive layer, and the first end and the second end are two opposite ends of the first conductive layer.

In the display panel of the present application, the first grooves and the first convex portions are disposed along a same direction.

In the display panel of the present application, the plurality of first grooves are equally spaced on a surface of the first conductive layer.

In the display panel of the present application, the plurality of first convex portions are equally spaced on a surface of the first conductive layer.

In the display panel of the present application, the light emitting layer includes an organic functional layer configured to emit light, a projection region of the organic functional layer on the first conductive layer along a direction perpendicular to a plane where the first conductive layer is located is a first region, and

the first grooves are at least distributed in the first region.

In the display panel of the present application, the first grating structure includes a nanometer grating.

In the display panel of the present application, the array substrate includes a plurality of thin film transistors,
the anode layer further includes a third conductive layer, and the third conductive layer is located on a side of the first conductive layer away from the second conductive layer.

In the display panel of the present application, the third conductive layer is electrically connected to the corresponding thin film transistors.

In the display panel of the present application, the third conductive layer includes indium tin oxide (ITO), the first conductive layer includes silver (Ag), and the second conductive layer includes ITO.

In the display panel of the present application, the display panel further includes a cathode disposed on the light emitting layer, and a surface of the cathode toward the light emitting layer is provided with a second grating structure.

In the display panel of the present application, the light emitting layer includes an organic functional layer configured to emit light, a projection region of the organic functional layer on the cathode along a direction perpendicular to a plane where the cathode is located is a second region, and

the second grating structure is at least distributed in the second region.

In the display panel of the present application, the second grating structure includes a plurality of second grooves and a plurality of second convex portions close to the second grooves.

In the display panel of the present application, the second grooves and the second convex portions are disposed along a same direction,
the plurality of second grooves are equally spaced on a surface of the cathode, and the plurality of second convex portions are equally spaced on the surface of the cathode.

In the display panel of the present application, the second grating structure includes a nanometer grating.

In the display panel of the present application, an orthogonal projection of the second grating structure on the first conductive layer overlaps the first grating structure.

The present application further provides a display panel, including:
an array substrate;
an anode layer disposed on the array substrate and including a first conductive layer and a second conductive layer located on the first conductive layer, wherein a surface of the first conductive layer toward the second conductive layer is provided with a first grating structure;
a light emitting layer disposed on the second conductive layer; and
a cathode disposed on the light emitting layer, wherein a surface of the cathode toward the light emitting layer is provided with a second grating structure;
wherein the first grating structure includes a plurality of first grooves and a plurality of first convex portions close to the first grooves, the first grooves and the first convex portions are disposed along a same direction and are equally spaced on a surface of the first conductive layer, the second grating structure includes a plurality of second grooves and a plurality of second convex portions close to the second grooves, and the second grooves and the second convex portions are disposed along a same direction and are equally spaced on a surface of the cathode.

The present application provides a display panel. The display panel includes an array substrate and an anode layer disposed on the array substrate. The anode layer includes a first conductive layer and a second conductive layer located on the first conductive layer. A surface of the first conductive layer toward the second conductive layer is provided with a first grating structure. The first conductive layer is a light-reflecting conductive layer. The second conductive layer is a light-transmitting conductive layer. A light emitting layer is disposed on the second conductive layer. In the present application, by disposing the first grating structure on the first conductive layer, surface plasmon effect and waveguide effect occurring in a dielectric layer near the anode are weakened, and an amount of light consumed by these two effects is reduced, which improves light extraction efficiency of the display panel.

### DESCRIPTION OF DRAWINGS

To more clearly illustrate embodiments or the technical solutions, the accompanying figures required for illustrating embodiments or the technical solutions of the present application will be described in brief. Obviously, the accompanying figures described below are only part of the embodiments of the present application, from which figures those skilled in the art can derive further figures without making any inventive efforts.

FIG. 1 is a schematic diagram of a first partial structure of a display panel provided by one embodiment of the present application.

FIG. 2 is a schematic diagram of a planar structure of a first conductive layer illustrated in FIG. 1.

FIG. 3 is a schematic diagram of another planar structure of the first conductive layer illustrated in FIG. 1.

FIG. 4 is a schematic diagram of a second partial structure of the display panel provided by one embodiment of the present application.

FIG. 5 is a schematic diagram of a third partial structure of the display panel provided by one embodiment of the present application.

FIG. 6 is a schematic diagram of a planar structure of a cathode illustrated in FIG. 5.

FIG. 7 is a schematic diagram of another planar structure of the cathode illustrated in FIG. 5.

FIG. 8 is a schematic diagram of a fourth partial structure of the display panel provided by one embodiment of the present application.

### DETAILED DESCRIPTION OF EMBODIMENTS

The descriptions of embodiments below refer to accompanying drawings in order to illustrate certain embodiments which the present application can implement. The directional terms of which the present application mentions, for example, “top,” “bottom,” “upper,” “lower,” “front,” “rear,” “left,” “right,” “inside,” “outside,” “side,” etc., are just refer to directions of the accompanying figures. Therefore, the used directional terms are for illustrating and understanding the present application, but not for limiting the present application. In the figures, units with similar structures are used same labels to indicate.

One embodiment of the present application provides a display panel. The display panel includes an array substrate and an anode layer disposed on the array substrate. The anode layer includes a first conductive layer and a second conductive layer located on the first conductive layer. A surface of the first conductive layer toward the second conductive layer is provided with a first grating structure. The first conductive layer is a light-reflecting conductive layer. The second conductive layer is a light-transmitting conductive layer. A light emitting layer is disposed on the second conductive layer. In the present application, by disposing the first grating structure on the first conductive layer, surface plasmon effect and waveguide effect occurring in a dielectric layer near the anode are weakened, and an amount of light consumed by these two effects is reduced, which is conducive to improving light extraction efficiency of the display panel.

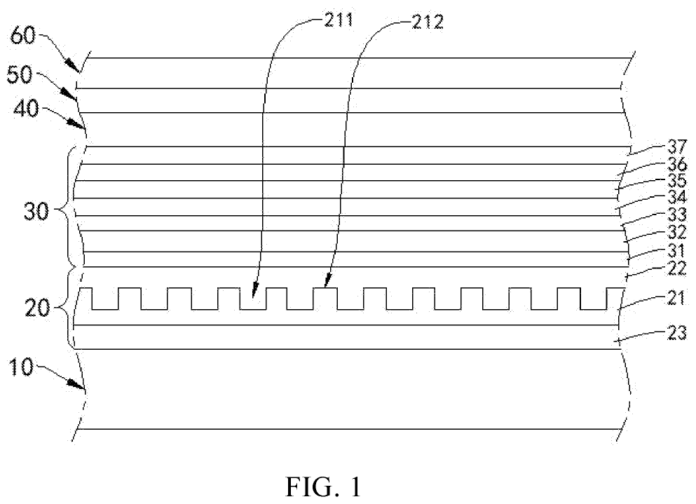

Please refer to FIG. 1. FIG. 1 is a schematic diagram of a first partial structure of a display panel provided by one embodiment of the present application. The display panel includes an array substrate 10, an anode layer 20 disposed on the array substrate 10, a light emitting layer 30 disposed on the anode layer 20, a cathode layer 40 disposed on the light emitting layer 30, an encapsulation layer 50 disposed on the cathode layer 40, and a light concentrating layer 60 disposed on the encapsulation layer 50.

A driving circuit is disposed in the array substrate 10. The driving circuit is electrically connected to the anode layer 20 to provide driving signals to the anode layer 20. The driving signal can include various driving signal wirings and a plurality of thin film transistor devices. The driving signal wirings and the thin film transistor devices can be arranged in an array manner.

The anode layer 20 includes a first conductive layer 21 and a second conductive layer 22 located on the first conductive layer 21. The light emitting layer 30 is located on the second conductive layer 22. The first conductive layer 21 is a light-reflecting conductive layer. The second conductive layer 22 is a light-transmitting conductive layer. Optionally, the anode layer 20 further includes a third conductive layer 23, and the third conductive layer 23 is located between the first conductive layer 21 and the array substrate 10. The third conductive layer 23, the first conductive layer 21, and the second conductive layer 22 together constitute the anode of the display panel.

Optionally, the third conductive layer 23 is an indium tin oxide (ITO) electrode, the first conductive layer 21 is a silver electrode, and the second conductive layer 22 is an ITO electrode.

Specifically, the first conductive layer 21 is a non-transparent metal conductive layer, and a part of the light emitted by the light emitting layer 30 is irradiated toward the anode layer 20 and is reflected by the anode layer 20, thereby emitting light from a light-exiting surface the display panel. When the light irradiates to the anode layer 20 and the film layers near the anode layer 20, a part of the light is consumed due to the surface plasmon effect and the waveguide effect. The greater the amount of light consumed by the surface plasmon effect and the waveguide effect is, the lesser the amount of light emitted from the light-exiting surface of the display panel is, and the lower the light extraction efficiency of the display panel is.

In this embodiment, a surface of the first conductive layer 21 toward the second conductive layer 22 is provided with a first grating structure, the first grating structure includes a plurality of first grooves 211 and a plurality of first convex portions 212 close to the first grooves 211, and the second conductive layer 22 is filled in the first grooves 211. In this embodiment, by disposing the first grating structure on the surface of the anode metal conductive layer, the amount of light consumed in a medium near the anode metal conductive layer due to the surface plasmon effect and the waveguide effect is reduced, the amount of light reflected by the anode is increased, and light extraction efficiency of the display panel is improved.

The cross-sectional shape of the first convex portions 212 along a direction perpendicular to a plane where the first conductive layer 21 is located includes a rectangular shape. The rectangular shape may be a rectangle or a square, so that the grating structure is formed on the first conductive layer 21. The first grating structure can be a nanometer grating. In this embodiment, by forming the first grating structure on the surface of the first conductive layer 21, the surface plasmon effect and the waveguide effect in the surface of the first conductive layer 21 and the film layers near the first conductive layer 21 are reduced, which is beneficial to improve the light extraction efficiency of the display panel.

Furthermore, the cross-sectional shape of the first conductive layer 21 along the direction perpendicular to the plane where the first conductive layer 21 is located includes a zigzag shape. In this embodiment, by using a characteristic of the zigzag shape of the first conductive layer 21, the surface plasmon effect and the waveguide effect in the surface of the first conductive layer 21 and the film layers near the first conductive layer 21 are reduced, thereby improving the light extraction efficiency of the display panel.

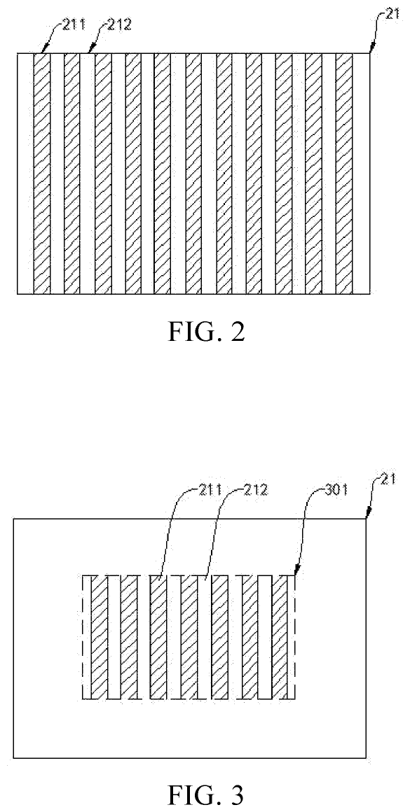

Please refer to FIG. 1 and FIG. 2. FIG. 2 is a schematic diagram of a planar structure of the first conductive layer illustrated in FIG. 1. The first grooves 211 extend from a first end of the first conductive layer 21 to a second end of the first conductive layer 21, and the first end and the second end are two opposite ends of the first conductive layer 21. The first grooves 211 and the first convex portions 212 are arranged alternately on the surface of the first conductive layer 21. The first convex portions 212 also extend from the first end of the first conductive layer 21 to the second end of the first conductive layer 21.

Optionally, the first grooves 211 and the first convex portions 212 extend along a straight line on the first conductive layer 21, or the first grooves 211 and the first convex portions 212 extend along a curve on the first conductive layer 21. The first grooves 211 and the first convex portions 212 are both equally spaced on the first conductive layer 21.

Optionally, please refer to FIG. 1 and FIG. 3. FIG. 3 is a schematic diagram of another planar structure of the first conductive layer illustrated in FIG. 1. The light emitting layer 30 includes an organic functional layer configured to emit light. A projection region of the organic functional layer on the first conductive layer 21 along the direction perpendicular to a plane where the first conductive layer 21 is located is a first region 301. The first grooves 211 and the first convex portions 212 are distributed in the first region 301. The first grooves 211 and the first convex portions 212 both extend from a first end of the first region 301 to another opposite end of the first region 301. The first grooves 211 and the first convex portions 212 can extend along a straight line or can also extend along a curve on the first conductive layer 21. The first grooves 211 and the first convex portions 212 are both equally spaced on a surface of the first conductive layer 21.

Furthermore, please refer to FIG. 1. The light emitting layer 30 includes a pixel definition layer and an organic functional layer disposed in an opening of the pixel definition layer. The organic functional layer includes a hole injection layer 31, a hole transport layer 32 located on the hole injection layer 31, an electron blocking layer 33 located on the hole transport layer 32, a light emitting functional layer 34 located on the electron blocking layer 33, an electron control layer 35 located on the light emitting functional layer 34, an electron transport layer 36 located on the electron control layer 35, and an electron injection layer 37 located on the electron transport layer 36.

The hole injection layer 31 and the hole transport layer 32 are configured to transmit electron holes to the light emitting functional layer 34. The electron blocking layer 33 is configured to block electrons. The electron injection layer 37, the electron transport layer 36, and the electron control layer 35 are configured to transmit electrons to the light emitting functional layer 34. The light emitting functional layer 34 is configured to combine the electron holes and electrons to emit light.

The cathode layer 40 includes a cathode. The cathode is electrically connected to the organic functional layer in the light emitting layer 30 and is configured to transmit electrons to the organic functional layer. Optionally, the cathode is made of an alloy of magnesium and silver.

The thin film encapsulation layer 50 can include a combined structure of an organic material layer and an inorganic material layer, which is configured to seal and protect the cathode layer 40 and the light emitting layer 30.

The light concentrating layer 60 includes a plurality of light concentrating structures and is configured to concentrate the light emitted by the light emitting layer 30 to a specific display region and to emit it, thereby further improving the light extraction efficiency of the display panel.

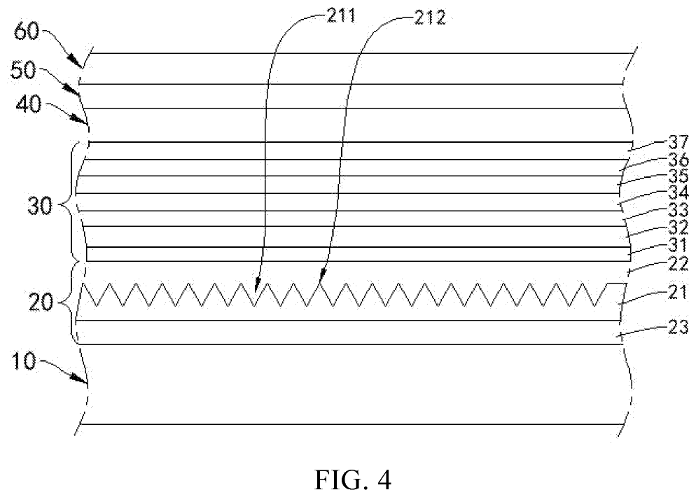

In one embodiment, please refer to FIG. 4. The display panel illustrated in FIG. 4 has same or similar structures as the display panel illustrated in FIG. 1. Structural characteristics of the display panel illustrated in FIG. 4 are described as follows. Wherein, for parts which are not described in detail, please refer to the aforesaid description of the structure of the display panel illustrated in FIG. 1.

The display panel includes an array substrate 10, an anode layer 20 disposed on the array substrate 10, a light emitting layer 30 disposed on the anode layer 20, a cathode layer 40 disposed on the light emitting layer 30, an encapsulation layer 50 disposed on the cathode layer 40, and a light concentrating layer 60 disposed on the encapsulation layer 50.

A driving circuit is disposed in the array substrate 10. The driving circuit is electrically connected to the anode layer 20 to provide driving signals to the anode layer 20. The driving signal can include various driving signal wirings and a plurality of thin film transistor devices. The driving signal wirings and the thin film transistor devices can be arranged in an array manner.

The anode layer 20 includes a first conductive layer 21 and a second conductive layer 22 located on the first conductive layer 21. The light emitting layer 30 is located on the second conductive layer 22. The first conductive layer 21 is a metal conductive layer. Optionally, the anode layer 20 further includes a third conductive layer 23, and the third conductive layer 23 is located between the first conductive layer 21 and the array substrate 10. The third conductive layer 23, the first conductive layer 21, and the second conductive layer 22 together constitute the anode of the display panel.

Optionally, the third conductive layer 23 is an indium tin oxide (ITO) electrode, the first conductive layer 21 is a silver electrode, and the second conductive layer 22 is an ITO electrode.

A surface of the first conductive layer 21 toward the second conductive layer 22 is provided with a first grating structure. The first grating structure includes a plurality of first grooves 211 and a plurality of first convex portions 212. The second conductive layer 22 is filled in the first grooves 211. A cross-sectional shape of the first convex portions 211 along a direction perpendicular to a plane where the first conductive layer 21 is located is triangular, thereby allowing the grating structure to form on the first conductive layer 21.

Optionally, the first grating structure can be a nanometer grating.

In this embodiment, by forming the first grating structure on the surface of the first conductive layer 21, the surface plasmon effect and the waveguide effect in the surface of the first conductive layer 21 and the film layers near the first conductive layer 21 are reduced, which is beneficial to improve the light extraction efficiency of the display panel.

Across-sectional shape of the first conductive layer 21 along the direction perpendicular to the plane where the first conductive layer 21 is located includes a zigzag shape. In this embodiment, by using a characteristic of the zigzag shape of the first conductive layer 21, the surface plasmon effect and the waveguide effect in the surface of the first conductive layer 21 and the film layers near the first conductive layer 21 are reduced, thereby improving the light extraction efficiency of the display panel.

Optionally, the first grooves 211 and the first convex portions 212 extend from a first end of the first conductive layer 21 to a second end of the first conductive layer 21, and the first end and the second end are two opposite ends of the first conductive layer 21.

Optionally, the light emitting layer 30 includes an organic functional layer configured to emit light. A projection region of the organic functional layer on the first conductive layer 21 along the direction perpendicular to a plane where the first conductive layer 21 is located is a first region. The first grooves 211 and the first convex portions 212 are distributed in the first region. The first grooves 211 and the first convex portions 212 both extend from a first end of the first region to another opposite end of the first region.

Optionally, the first grooves 211 and the first convex portions 212 both extend along a straight line or both extend along a curve on the first conductive layer 21. The first grooves 211 and the first convex portions 212 are both equally spaced on a surface of the first conductive layer 21.

Furthermore, the light emitting layer 30 includes a pixel definition layer and an organic functional layer disposed in an opening of the pixel definition layer. The organic functional layer includes a hole injection layer 31, a hole transport layer 32 located on the hole injection layer 31, an electron blocking layer 33 located on the hole transport layer 32, a light emitting functional layer 34 located on the electron blocking layer 33, an electron control layer 35 located on the light emitting functional layer 34, an electron transport layer 36 located on the electron control layer 35, and an electron injection layer 37 located on the electron transport layer 36.

The hole injection layer 31 and the hole transport layer 32 are configured to transmit electron holes to the light emitting functional layer 34. The electron blocking layer 33 is configured to block electrons. The electron injection layer 37, the electron transport layer 36, and the electron control layer 35 are configured to transmit electrons to the light emitting functional layer 34. The light emitting functional layer 34 is configured to combine the electron holes and electrons to emit light.

The cathode layer 40 includes a cathode. The cathode is electrically connected to the organic functional layer in the light emitting layer 30 and is configured to transmit electrons to the organic functional layer. Optionally, the cathode is made of an alloy of magnesium and silver.

The thin film encapsulation layer 50 can include a combined structure of an organic material layer and an inorganic material layer, which is configured to seal and protect the cathode layer 40 and the light emitting layer 30.

The light concentrating layer 60 includes a plurality of light concentrating structures and is configured to concentrate the light emitted by the light emitting layer 30 to a specific display region and to emit it to improve the light extraction efficiency of the display panel.

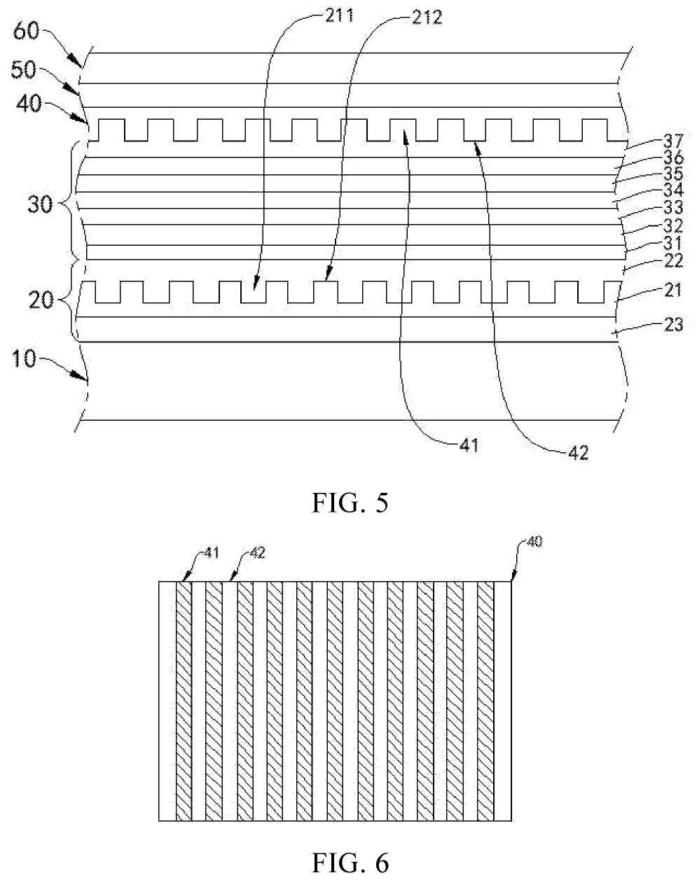

In one embodiment, please refer to FIG. 5. The display panel illustrated in FIG. 5 has same or similar structures as the display panel illustrated in FIG. 1. Structural characteristics of the display panel illustrated in FIG. 5 are described as follows. Wherein, for parts which are not described in detail, please refer to the aforesaid description of the structure of the display panel illustrated in FIG. 1.

The display panel includes an array substrate 10, an anode layer 20 disposed on the array substrate 10, a light emitting layer 30 disposed on the anode layer 20, a cathode layer 40 disposed on the light emitting layer 30, an encapsulation layer 50 disposed on the cathode layer 40, and a light concentrating layer 60 disposed on the encapsulation layer 50.

A driving circuit is disposed in the array substrate 10. The driving circuit is electrically connected to the anode layer 20 to provide driving signals to the anode layer 20. The driving signal can include various driving signal wirings and a plurality of thin film transistor devices. The driving signal wirings and the thin film transistor devices can be arranged in an array manner.

The anode layer 20 includes a first conductive layer 21 and a second conductive layer 22 located on the first conductive layer 21. The light emitting layer 30 is located on the second conductive layer 22. The first conductive layer 21 is a metal conductive layer. Optionally, the anode layer 20 further includes a third conductive layer 23, and the third conductive layer 23 is located between the first conductive layer 21 and the array substrate 10. The third conductive layer 23, the first conductive layer 21, and the second conductive layer 22 together constitute the anode of the display panel.

Optionally, the third conductive layer 23 is an indium tin oxide (ITO) electrode, the first conductive layer 21 is a silver electrode, and the second conductive layer 22 is an ITO electrode.

A surface of the first conductive layer 21 toward the second conductive layer 22 is provided with a first grating structure. The first grating structure includes a plurality of first grooves 211 and a plurality of first convex portions 212. The second conductive layer 22 is filled in the first grooves 211.

Across-sectional shape of the first conductive layer 21 along the direction perpendicular to the plane where the first conductive layer 21 is located includes a zigzag shape. In this embodiment, by using a characteristic of the zigzag shape of the first conductive layer 21, the surface plasmon effect and the waveguide effect in the surface of the first conductive layer 21 and the film layers near the first conductive layer 21 are reduced, thereby improving the light extraction efficiency of the display panel.

Optionally, the first grooves 211 and the first convex portions 212 extend from a first end of the first conductive layer 21 to a second end of the first conductive layer 21, and the first end and the second end are two opposite ends of the first conductive layer 21.

Optionally, the light emitting layer 30 includes an organic functional layer configured to emit light. A projection region of the organic functional layer on the first conductive layer 21 along the direction perpendicular to a plane where the first conductive layer 21 is located is a first region. The first grooves 211 and the first convex portions 212 are distributed in the first region. The first grooves 211 and the first convex portions 212 both extend from a first end of the first region to another opposite end of the first region.

Optionally, the first grooves 211 and the first convex portions 212 both extend along a straight line or both extend along a curve on the first conductive layer 21. The first grooves 211 and the first convex portions 212 are both equally spaced on the first conductive layer 21.

The light emitting layer 30 includes a pixel definition layer and an organic functional layer disposed in an opening of the pixel definition layer. The organic functional layer includes a hole injection layer 31, a hole transport layer 32 located on the hole injection layer 31, an electron blocking layer 33 located on the hole transport layer 32, a light emitting functional layer 34 located on the electron blocking layer 33, an electron control layer 35 located on the light emitting functional layer 34, an electron transport layer 36 located on the electron control layer 35, and an electron injection layer 37 located on the electron transport layer 36.

The hole injection layer 31 and the hole transport layer 32 are configured to transmit electron holes to the light emitting functional layer 34. The electron blocking layer 33 is configured to block electrons. The electron injection layer 37, the electron transport layer 36, and the electron control layer 35 are configured to transmit electrons to the light emitting functional layer 34. The light emitting functional layer 34 is configured to combine the electron holes and electrons to emit light.

The cathode layer 40 includes a cathode. The cathode is electrically connected to the organic functional layer in the light emitting layer 30 and is configured to transmit electrons to the organic functional layer. Optionally, the cathode is made of an alloy of magnesium and silver.

Furthermore, a surface of the cathode toward the light emitting layer 30 is provided with a second grating structure. The second grating structure includes a plurality of second grooves 41 and a plurality of second convex portions 42. In this embodiment, by disposing the second grating structure on the surface of the cathode, an amount of light consumed by surface plasmon effect and waveguide effect occurring in a medium near the cathode is reduced, the amount of light reflected by the anode is increased, and light extraction efficiency of the display panel is improved.

A cross-sectional shape of the second convex portions 42 along a direction perpendicular to a plane where the cathode layer 40 is located includes a rectangular shape or a triangular shape. A cross-sectional shape of the cathode along a direction perpendicular to a plane where the cathode layer 40 is located includes a zigzag shape, thereby allowing the grating structure to be formed on the cathode layer 40. The second grating structure can be a nanometer grating.

Optionally, please refer to FIG. 5 and FIG. 6. FIG. 6 is a schematic diagram of a planar structure of the cathode illustrated in FIG. 5. The second grooves 41 extend from one end of the cathode to another opposite end of the cathode. The second grooves 41 and the second convex portions 42 are arranged alternately on the surface of the cathode. Optionally, the second grooves 41 and the second convex portions 42 both extend along a straight line or both extend along a curve on the cathode. The second grooves 41 and the second convex portions 42 are both equally spaced on a surface of the cathode.

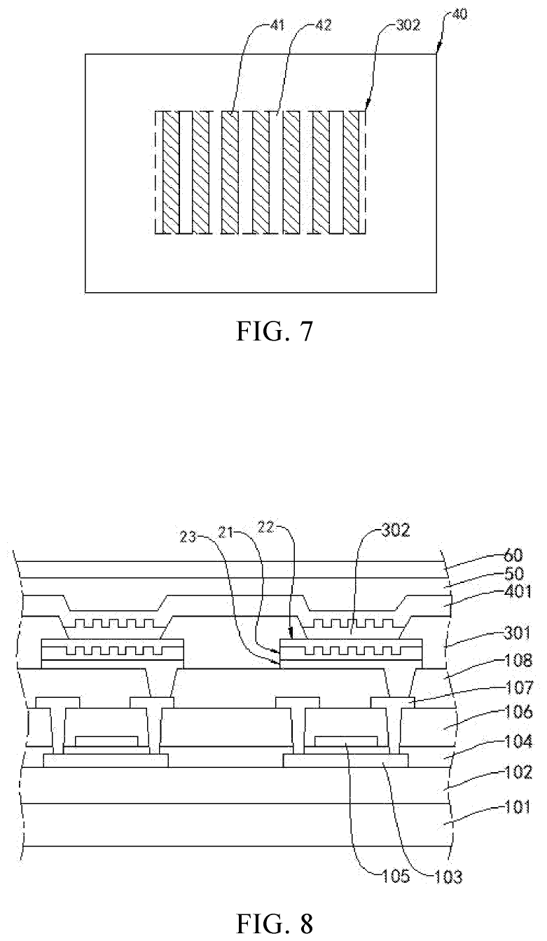

Optionally, please refer to FIG. 5 and FIG. 7. FIG. 7 is a schematic diagram of another planar structure of the cathode illustrated in FIG. 5. A projection region of the organic functional layer in the light emitting layer 30 on the cathode along a direction perpendicular to a plane where the cathode layer 40 is located is a second region 302. The second grooves 41 and the second convex portions 42 are distributed in the second region 302. The second grooves 41 and the second convex portions 42 both extend from one end of the second region 302 to another opposite end of the second region 302. The second grooves 41 and the second convex portions 42 can extend along a straight line or can also extend along a curve on the cathode. The second grooves 41 and the second convex portions 42 are both equally spaced on a surface of the cathode.

Optionally, orthogonal projections of the second grooves 41 on the first conductive layer 21 overlap the first grooves 211.

The thin film encapsulation layer 50 can include a combined structure of an organic material layer and an inorganic material layer, which is configured to seal and protect the cathode layer 40 and the light emitting layer 30.

The light concentrating layer 60 includes a plurality of light concentrating structures and is configured to concentrate the light emitted by the light emitting layer 30 to a specific display region and to emit it to improve the light extraction efficiency of the display panel.

In one embodiment, please refer to FIG. 8. FIG. 8 is a schematic diagram of a fourth partial structure of the display panel provided by one embodiment of the present application. The display panel illustrated in FIG. 8 has same or similar structures as the display panel illustrated in FIG. 1. Structural characteristics of the display panel illustrated in FIG. 8 are described as follows. Wherein, for parts which are not described in detail, please refer to the aforesaid description of the structure of the display panel illustrated in FIG. 1.

The display panel includes an array substrate, an anode layer disposed on the array substrate, a light emitting layer disposed on the anode layer, a cathode layer disposed on the light emitting layer, an encapsulation layer 50 disposed on the cathode layer, and a light concentrating layer 60 disposed on the encapsulation layer 50.

The array substrate includes a base substrate 101, a buffer layer 102 disposed on the base substrate 101, a semiconductor layer 103 disposed on the buffer layer 102, a gate insulating layer 104 covering the semiconductor layer 103, a gate electrode 105 disposed on the gate insulating layer 104, an interlayer insulating layer 106 covering the gate electrode 105, source and drain electrodes 107 disposed on the interlayer insulating layer 106, and a planarization layer 108 covering the source and drain electrodes 107. The source and drain electrodes 107 are connected to two opposite ends of the semiconductor layer 103 through via holes on the gate insulating layer 104 and the interlayer insulation layer 106. The semiconductor layer 103, the gate electrode 105, and the source and drain electrodes 107 constitute a thin film transistor.

The anode layer includes a third conductive layer 23 located on the planarization layer 108, the first conductive layer 21 located on the third conductive layer 23, and the second conductive layer 22 located on the first conductive layer 21. The first conductive layer 21 is a metal conductive layer.

Optionally, the third conductive layer 23 is an indium tin oxide (ITO) electrode, the first conductive layer 21 is a silver electrode, and the second conductive layer 22 is an ITO electrode.

A surface of the first conductive layer 21 toward the second conductive layer 22 is provided with a first grating structure. The second conductive layer 22 is filled in grooves of the first grating structure. In this embodiment, by forming the first grating structure on the surface of the first conductive layer 21, the surface plasmon effect and the waveguide effect in the surface of the first conductive layer 21 and the film layers near the first conductive layer 21 are reduced, which is beneficial to improve the light extraction efficiency of the display panel.

The light emitting layer includes a pixel definition layer 301 and an organic functional layer 302 disposed in an opening of the pixel definition layer 301. The organic functional layer 302 can include various film layer structures configured to realize a light emitting function.

The cathode layer includes a cathode 401. A surface of the cathode 401 toward the light emitting layer is provided with the second grating structure. In this embodiment, by disposing the second grating structure on the surface of the cathode, an amount of light consumed by surface plasmon effect and waveguide effect occurring in a medium near the cathode is reduced, the amount of light reflected by the anode is increased, and light extraction efficiency of the display panel is improved.

The thin film encapsulation layer 50 can include a combined structure of an organic material layer and an inorganic material layer, which is configured to seal and protect the cathode layer 40 and the light emitting layer 30.

The light concentrating layer 60 includes a plurality of light concentrating structures and is configured to concentrate the light emitted by the light emitting layer 30 to a specific display region and to emit it, thereby further improving the light extraction efficiency of the display panel.

In summary, the display panel provided by embodiments of the present application includes the array substrate and the anode layer disposed on the array substrate. The anode layer includes the first conductive layer and the second conductive layer located on the first conductive layer. The surface of the first conductive layer toward the second conductive layer is provided with the first grating structure. The first conductive layer is a light-reflecting conductive layer. The second conductive layer is a light-transmitting conductive layer. The light emitting layer is disposed on the second conductive layer. In the present application, by disposing the first grating structure on the first conductive layer on the surface of the metal conductive layer of the anode, the surface plasmon effect and the waveguide effect occurring in a dielectric layer near the anode are weakened, and an amount of light consumed by these two effects is reduced, which is conducive to improving the light extraction efficiency of the display panel.

One embodiment of the present application further provides a display device. The display device includes the display panel provided by the embodiments of the present application. The display device can be a device having display functions, such as a mobile phone, a laptop, a tablet PC, a television, a global positioning system, etc.

It should be noted that although the present application has disclosed the specific embodiments as above, the above-mentioned embodiments are not to limit to the present application. A person skilled in the art can make any change and modification; therefore, the scope of protection of the present application is subject to the scope defined by the claims.

What is claimed is:

1. A display panel, comprising:
an array substrate;
an anode layer disposed on the array substrate and comprising a first conductive layer and a second conductive layer located on the first conductive layer, wherein a surface of the first conductive layer toward the second conductive layer is provided with a first grating structure; and
a light emitting layer disposed on the second conductive layer.

2. The display panel as claimed in claim 1, wherein the first conductive layer is a light-reflecting conductive layer, and the second conductive layer is a light-transmitting conductive layer.

3. The display panel as claimed in claim 1, wherein the first grating structure comprises a plurality of first grooves and a plurality of first convex portions close to the first grooves.

4. The display panel as claimed in claim 3, wherein a cross-sectional shape of the first convex portions along a direction perpendicular to a plane where the first conductive layer is located is any one of square, triangular, trapezoidal, or arc.

5. The display panel as claimed in claim 3, wherein the first grooves extend from a first end of the first conductive layer to a second end of the first conductive layer, and the first end and the second end are two opposite ends of the first conductive layer.

6. The display panel as claimed in claim 5, wherein the first grooves and the first convex portions are disposed along a same direction.

7. The display panel as claimed in claim 5, wherein the plurality of first grooves are equally spaced on a surface of the first conductive layer.

8. The display panel as claimed in claim 5, wherein the plurality of first convex portions are equally spaced on a surface of the first conductive layer.

9. The display panel as claimed in claim 3, wherein
the light emitting layer comprises an organic functional layer configured to emit light,
a projection region of the organic functional layer on the first conductive layer along a direction perpendicular to a plane where the first conductive layer is located is a first region, and
the first grooves are at least distributed in the first region.

10. The display panel as claimed in claim 1, wherein the first grating structure comprises a nanometer grating.

11. The display panel as claimed in claim 1, wherein the array substrate comprises a plurality of thin film transistors,
the anode layer further comprises a third conductive layer, and the third conductive layer is located on a side of the first conductive layer away from the second conductive layer.

12. The display panel as claimed in claim 11, wherein the third conductive layer is electrically connected to the corresponding thin film transistors.

13. The display panel as claimed in claim 11, wherein the third conductive layer comprises indium tin oxide (ITO), the first conductive layer comprises silver (Ag), and the second conductive layer comprises ITO.

14. The display panel as claimed in claim 1, wherein the display panel further comprises a cathode disposed on the light emitting layer, and a surface of the cathode toward the light emitting layer is provided with a second grating structure.

15. The display panel as claimed in claim 14, wherein the light emitting layer comprises an organic functional layer configured to emit light, a projection region of the organic functional layer on the cathode along a direction perpendicular to a plane where the cathode is located is a second region, and
the second grating structure is at least distributed in the second region.

16. The display panel as claimed in claim 14, wherein the second grating structure comprises a plurality of second grooves and a plurality of second convex portions close to the second grooves.

17. The display panel as claimed in claim 16, wherein the second grooves and the second convex portions are disposed along a same direction,
the plurality of second grooves are equally spaced on a surface of the cathode, and the plurality of second convex portions are equally spaced on the surface of the cathode.

18. The display panel as claimed in claim 14, wherein the second grating structure comprises a nanometer grating.

19. The display panel as claimed in claim 14, wherein an orthogonal projection of the second grating structure on the first conductive layer overlaps the first grating structure.

20. A display panel, comprising:
an array substrate;
an anode layer disposed on the array substrate and comprising a first conductive layer and a second conductive layer located on the first conductive layer, wherein a surface of the first conductive layer toward the second conductive layer is provided with a first grating structure;
a light emitting layer disposed on the second conductive layer; and
a cathode disposed on the light emitting layer, wherein a surface of the cathode toward the light emitting layer is provided with a second grating structure;
wherein the first grating structure comprises a plurality of first grooves and a plurality of first convex portions close to the first grooves, the first grooves and the first convex portions are disposed along a same direction and are equally spaced on a surface of the first conductive layer, the second grating structure comprises a plurality of second grooves and a plurality of second convex portions close to the second grooves, and the second grooves and the second convex portions are disposed along a same direction and are equally spaced on a surface of the cathode.
